(19) United States
(12) Patent Application Publication
(10) Pub. No.: US 2024/0027891 A1
(43) Pub. Date: Jan. 25, 2024

(54) REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventor: Kazuhiro HAMAMOTO, Tokyo (JP)

(73) Assignee: HOYA CORPORATION, Tokyo (JP)

(21) Appl. No.: 18/266,057

(22) PCT Filed: Dec. 15, 2021
(86) PCT No.: PCT/JP2021/046193

§ 371 Date: Jun. 8, 2023

(30) Foreign Application Priority Data
Dec. 25, 2020 (JP) 2020-217573

(51) Int. Cl. G03F 1/24; G03F 1/58

(52) U.S. Cl. CPC G03F 1/24; G03F 1/58

(57) ABSTRACT

Provided is a reflective mask blank that makes it possible to form a transfer pattern having a fine pattern shape on a transferred substrate and that is used for manufacturing a reflective mask having a transfer pattern capable of performing EUV exposure with a high throughput.

A reflective mask blank comprises: a substrate; a multilayer reflective film on the substrate; and an absorber film on the multilayer reflective film. The absorber film comprises iridium (Ir) and an additive element. The additive element is at least one selected from boron (B), silicon (Si), phosphorus (P), titanium (Ti), germanium (Ge), arsenic (As), selenium (Se), niobium (Nb), molybdenum (Mo), ruthenium (Ru), and tantalum (Ta). The content of the iridium (Ir) in the absorber film is more than 50 atom %.

### CROSS-REFERENCE TO RELATED APPLICATIONS

This application is the National Stage of International Application No. PCT/JP2021/046193, filed Dec. 15, 2021, which claims priority to Japanese Patent Application No. 2020-217573, filed Dec. 25, 2020, and the contents of which is incorporated by reference.

### TECHNICAL FIELD

The present disclosure relates to a reflective mask blank that is an original plate for manufacturing an exposure mask used for, for example, manufacturing a semiconductor device, a reflective mask, and a method for manufacturing a semiconductor device using the reflective mask.

### BACKGROUND ART

Types of light sources of exposure apparatuses in manufacturing a semiconductor device are a g-line having a wavelength of 436 nm, an i-line having a wavelength of 365 nm, a KrF laser having a wavelength of 248 nm, and an ArF laser having a wavelength of 193 nm, and the wavelengths have been shortened gradually. In order to achieve finer pattern transfer, extreme ultra violet (EUV) lithography using EUV having a wavelength around 13.5 nm has been developed. In EUV lithography, a reflective mask is used because there are few materials transparent to EUV light. The reflective mask has a multilayer reflective film for reflecting exposure light on a low thermal expansion substrate. A basic structure of the reflective mask is a structure in which a desired transfer pattern is formed on a protective film for protecting the multilayer reflective film. In addition, as a typical reflective mask, there are a binary type reflective mask and a phase shift type reflective mask (halftone phase shift type reflective mask). A transfer pattern of the binary type reflective mask is formed of a relatively thick absorber pattern that sufficiently absorbs EUV light. A transfer pattern of the phase shift type reflective mask is formed of a relatively thin absorber pattern that reduces EUV light by light absorption and generates reflected light having a phase substantially inverted (phase inverted by about 180°) with respect to reflected light from the multilayer reflective film. The phase shift type reflective mask (halftone phase shift type reflective mask) has a resolution improving effect because a high transfer optical image contrast can be obtained by a phase shift effect like a transmission type optical phase shift mask. In addition, since an absorber pattern (phase shift pattern) of the phase shift type reflective mask has a thin film thickness, an accurate and fine phase shift pattern can be formed.

In EUV lithography, a projection optical system including a large number of reflecting mirrors is used due to light transmittance. EUV light is made obliquely incident on the reflective mask to cause these reflecting mirrors not to block projection light (exposure light). At present, an incident angle is mainly set to 6° with respect to a vertical plane of a reflective mask substrate. Along with improvement of a numerical aperture (NA) of the projection optical system, studies are being conducted toward making the incident angle about 8° that is a more oblique incident angle.

In EUV lithography, since exposure light is obliquely incident, there is an inherent problem called a shadowing effect. The shadowing effect is a phenomenon in which exposure light is obliquely incident on an absorber pattern having a three-dimensional structure, whereby a shadow is formed and a dimension and position of a transferred and formed pattern change. The three-dimensional structure of the absorber pattern serves as a wall to form a shadow on a shade side, and the dimension and position of the transferred and formed pattern change. For example, a difference occurs in a dimension and position of a transfer pattern between both cases, a case where the orientation of the absorber pattern to be arranged is parallel to a direction of obliquely incident light and a case where the orientation of the absorber pattern to be formed is perpendicular to the direction of the obliquely incident light, thereby decreasing transfer accuracy.

Patent Documents 1 and 2 disclose techniques related to such a reflective mask for EUV lithography and a mask blank for manufacturing the same. In addition, Patent Document 1 describes providing a reflective mask having a small shadowing effect, capable of phase shift exposure, and having sufficient light shielding frame performance. Conventionally, by using a phase shift type reflective mask as the reflective mask for EUV lithography, the film thickness of a phase shift pattern is made relatively thinner than that in a case of a binary type reflective mask. By making the film thickness of the phase shift pattern relatively thin, it is possible to suppress a decrease in transfer accuracy due to the shadowing effect.

Patent Document 3 describes a mask for EUV lithography. Specifically, the mask described in Patent Document 3 includes a substrate, a multilayer coating applied to the substrate, and a mask structure applied to the multilayer coating and having an absorber material. Patent Document 3 describes that the mask structure has a maximum thickness of less than 100 nm.

Patent Document 4 describes a method for manufacturing an extreme ultraviolet (EUV) mask blank. Specifically, it is described that the method described in Patent Document 4 includes: disposing a substrate, forming a stack formed of a plurality of reflection layers on the substrate, forming a capping layer on the stack formed of the plurality of reflection layers, and forming an absorption layer on the capping layer. In addition, Patent Document 4 describes that the absorption layer contains an alloy made of at least two different absorption materials.

Patent Document 5 describes a reflective mask blank including a substrate, a multilayer reflective film that is formed on the substrate and reflects exposure light, an absorber film that is formed on the multilayer reflective film and absorbs exposure light, and a buffer layer. Furthermore, Patent Document 5 describes that the buffer layer is disposed between the multilayer reflective film and the absorber film and has etching characteristics different from those of the absorber film. In addition, Patent Document describes that the absorber film is made of a material containing tantalum (Ta) as a main component and further containing at least one element selected from tellurium (Te), antimony (Sb), platinum (Pt), iodine (I), bismuth (Bi), iridium (Ir), osmium (Os), tungsten (W), rhenium (Re), tin (Sn), indium (In), polonium (Po), iron (Fe), gold (Au), mercury (Hg), gallium (Ga), and aluminum (Al).

In addition, Patent Document 6 describes a lithography reflective mask on which a pattern as an original plate is formed and which is used in order to project the pattern on an exposure target by reflecting a soft X-ray or a vacuum ultraviolet ray from a light source. In the lithography reflective mask of Patent Document 6, the pattern is formed of an absorber pattern formed on a reflecting portion that reflects the soft X-ray or vacuum ultraviolet ray, 0.29<k/|δ|<1.12 is satisfied when a wavelength of the soft X-ray or vacuum ultraviolet ray is represented by λ and an optical constant of a substance forming the absorber pattern is represented by 1−δ−ik (δ and k are real numbers, and i is an imaginary unit), and a thickness d of the absorber pattern satisfies 3λ/(16|δ|)<d<5λ/(16|δ|).

### PRIOR ART DOCUMENTS

### Patent Documents

Patent Document 1: JP 2009-212220 A
Patent Document 2: JP 2004-39884 A
Patent Document 3: JP 2013-532381 A
Patent Document 4: JP 2019-527382 A
Patent Document 5: JP 2007-273678 A
Patent Document 6: JP H07-114173 A

### DISCLOSURE OF INVENTION

In EUV lithography, a resist transfer pattern is transferred onto a resist layer formed on a transferred substrate (semiconductor substrate) using a transfer pattern formed on a reflective mask. A predetermined fine circuit is formed in a semiconductor device using the resist transfer pattern.

In order to improve performance such as electrical characteristics of the semiconductor device, to improve the degree of integration, and to reduce a chip size, it is required to make the transfer pattern finer, that is, to make the dimension of the transfer pattern smaller and to improve positional accuracy of the transfer pattern. Therefore, EUV lithography is required to have transfer performance for transferring a transfer pattern having a higher level of accuracy and a finer dimension than conventional ones. At present, it is required to form an ultra-fine and highly accurate transfer pattern applicable to a half pitch 16 nm (hp 16 nm) generation. In response to such a requirement, the transfer pattern formed on the reflective mask is also required to be further finer. In addition, in order to reduce the shadowing effect at the time of EUV exposure, it is required to further reduce the thickness of a thin film constituting the transfer pattern of the reflective mask. Specifically, the film thickness of the absorber film (phase shift film) of the reflective mask is required to be 50 nm or less.

Furthermore, as the transfer pattern is finer, the pattern shape of the transfer pattern is also diversified. Therefore, an absorber film for forming a transfer pattern applicable to diversified pattern shapes is required for the reflective mask.

In addition, in order to manufacture a semiconductor device at low cost, it is required that EUV exposure of EUV lithography can be performed with a high throughput.

As disclosed in Patent Documents 1 and 2, Ta has been conventionally used as a material for forming an absorber film (phase shift film) of a reflective mask blank. However, Ta has a refractive index (n) of about 0.943 in EUV light (for example, wavelength 13.5 nm). When a phase shift effect of a Ta thin film is used, the film thickness of an absorber film (phase shift film) made only of Ta is reduced to 60 nm that is a lowest limit. In order to further reduce the thickness, a metal material having a high extinction coefficient (k) (high absorption effect) can be used as an absorber film of a binary type reflective mask blank. For example, Patent Documents 3 and 4 describe platinum (Pt) and iridium (Ir) as a metal material having a large extinction coefficient (k) at a wavelength of 13.5 nm.

When the absorber film has a phase shift effect, a metal material having a low refractive index (n) is preferably used as the absorber film. By using a metal material having a low refractive index (n), a high transfer optical image contrast can be obtained by the phase shift effect at the time of exposure in EUV lithography.

Therefore, an aspect of the present disclosure is to provide a reflective mask blank that makes it possible to form a transfer pattern having a fine pattern shape on a transferred substrate and that is used for manufacturing a reflective mask having a transfer pattern capable of performing EUV exposure with a high throughput. Specifically, an aspect of the present disclosure is to provide a reflective mask blank having an absorber film having a small refractive index (n), a high extinction coefficient (k), and good processing characteristics.

In addition, an aspect of the present disclosure is to provide a reflective mask that makes it possible to form a transfer pattern having a fine pattern shape on a transferred substrate and that has a transfer pattern capable of performing EUV exposure with a high throughput. In addition, an aspect of the present disclosure is to provide a method for manufacturing a semiconductor device capable of forming diversified fine pattern shapes on a transferred substrate with a high throughput.

In order to solve the above problems, an embodiment of the present disclosure has the following configurations.

(Configuration 1)

Configuration 1 of the present embodiment is a reflective mask blank comprising: a substrate; a multilayer reflective film on the substrate; and an absorber film on the multilayer reflective film, in which
the absorber film comprises iridium (Ir) and an additive element,
the additive element is at least one selected from boron (B), silicon (Si), phosphorus (P), titanium (Ti), germanium (Ge), arsenic (As), selenium (Se), niobium (Nb), molybdenum (Mo), ruthenium (Ru), and tantalum (Ta), and
a content of the iridium (Ir) in the absorber film is more than 50 atom %.

(Configuration 2)

Configuration 2 of the present embodiment is the reflective mask blank according to configuration 1, in which the additive element comprises tantalum (Ta).

(Configuration 3)

Configuration 3 of the present embodiment is the reflective mask blank according to configuration 1 or 2, in which the additive element comprises tantalum (Ta), and a content of the tantalum (Ta) in the absorber film is 2 to 30 atom %.

(Configuration 4)

Configuration 4 of the present embodiment is the reflective mask blank according to any one of configurations 1 to 3, in which the absorber film further comprises oxygen (O), and a content of the oxygen (O) is 5 atom % or more.

(Configuration 5)

Configuration 5 of the present embodiment is the reflective mask blank according to any one of configurations 1 to 4, in which
the absorber film comprises a buffer layer and an absorption layer disposed on the buffer layer,
the buffer layer comprises chromium (Cr), and
the absorption layer comprises the iridium (Ir) and the additive element.

(Configuration 6)

Configuration 6 of the present embodiment is the reflective mask blank according to configuration 5, in which the absorber film has a film thickness of 50 nm or less, and the buffer layer has a film thickness of 10 nm or less.

(Configuration 7)

Configuration 7 of the present embodiment is a reflective mask comprising an absorber pattern in which the absorber film in the reflective mask blank according to any one of configurations 1 to 6 is patterned.

(Configuration 8)

Configuration 8 of the present embodiment is a method for manufacturing a reflective mask, the method comprising patterning the absorber film of the reflective mask blank according to any one of configurations 1 to 6 to form an absorber pattern.

(Configuration 9)

Configuration 9 of the present embodiment is a method for manufacturing a semiconductor device, the method comprising setting the reflective mask according to configuration 7 in an exposure apparatus comprising an exposure light source that emits EUV light and transferring a transfer pattern onto a resist film formed on a transferred substrate.

According to an embodiment of the present disclosure, it is possible to provide a reflective mask blank that makes it possible to form a transfer pattern having a fine pattern shape on a transferred substrate and that is used for manufacturing a reflective mask having a transfer pattern capable of performing EUV exposure with a high throughput. Specifically, according to the embodiment of the present disclosure, it is possible to provide a reflective mask blank having an absorber film having a small refractive index (n), a high extinction coefficient (k), and good processing characteristics.

In addition, according to the embodiment of the present disclosure, it is possible to provide a reflective mask that makes it possible to form a transfer pattern having a fine pattern shape on a transferred substrate and that has a transfer pattern capable of performing EUV exposure with a high throughput. In addition, according to the embodiment of the present disclosure, it is possible to provide a method for manufacturing a semiconductor device capable of forming diversified fine pattern shapes on a transferred substrate with a high throughput.

### BRIEF DESCRIPTION OF DRAWINGS

FIG. 1 is a schematic main part cross-sectional view for describing a schematic configuration of a reflective mask blank of the present disclosure.

FIG. 2 is a schematic main part cross-sectional view for describing a schematic configuration of a reflective mask blank according to another aspect of the present disclosure.

FIGS. 3A to 3D are process diagrams illustrating a process for preparing a reflective mask from a reflective mask blank in a schematic main part cross-sectional view.

FIG. 4 is a diagram illustrating a value of a normalized evaluation function obtained by simulation #1a, and is a diagram illustrating a distribution of values of the normalized evaluation function with respect to a refractive index (n) and an extinction coefficient (k) of an absorber film when a reflective mask has a vertical line-and-space (L/S) pattern of hp 16 nm and uses a RuNb film as a protective film (Cap film).

FIG. 5 is a diagram combining distributions of values of the normalized evaluation function obtained by simulations, and is a diagram illustrating a distribution in a case where values of the normalized evaluation function obtained as simulations #1a to #3a and #1b to #3b are all 1.015 or more (white) and a distribution in other cases (black).

### DESCRIPTION OF EMBODIMENTS

Hereinafter, an embodiment of the present disclosure will be specifically described with reference to the drawings. Note that each of the following embodiments is one mode for embodying the present disclosure and does not limit the present disclosure within the scope thereof. Note that in the drawings, the same or corresponding parts are denoted by the same reference signs, and description thereof may be simplified or omitted.

<Configuration of Reflective Mask Blank 100 and Method of Manufacturing the Same>

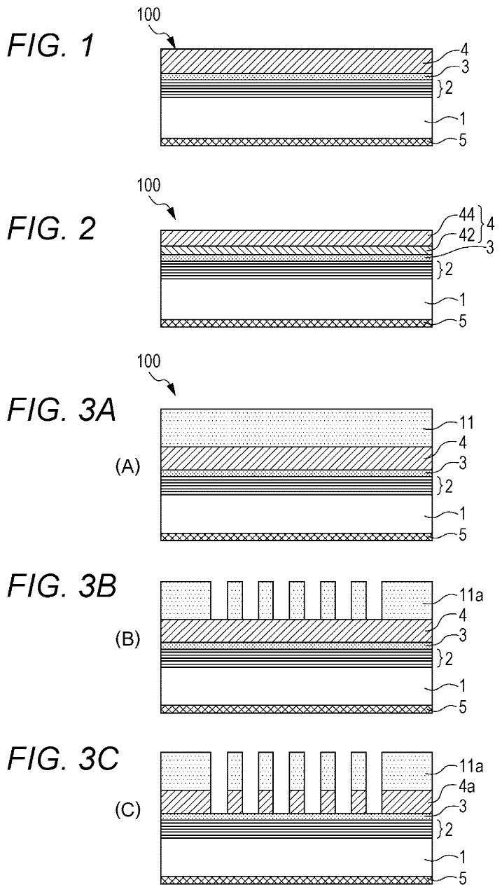

FIG. 1 is a schematic main part cross-sectional view for describing a configuration of a reflective mask blank 100 of an embodiment of the present disclosure. As illustrated in FIG. 1, the reflective mask blank 100 of the present embodiment includes a substrate 1, a multilayer reflective film 2 on the substrate 1, and an absorber film 4 on the multilayer reflective film 2. In the present specification, a surface of the substrate 1 on which the multilayer reflective film 2 is formed may be referred to as a first main surface (front surface). The absorber film 4 of the reflective mask blank 100 of the present embodiment contains iridium (Ir) and a predetermined additive element. The reflective mask blank 100 of the present embodiment can include a protective film 3 between the multilayer reflective film 2 and the absorber film 4. In addition, a conductive back film 5 for electrostatic chuck can be formed on a second main surface (back surface) side of the substrate 1.

By using the reflective mask blank 100 of the present embodiment, it is possible to manufacture a reflective mask 200 that makes it possible to form a transfer pattern having a fine pattern shape on a transferred substrate and that has a transfer pattern capable of performing EUV exposure with a high throughput. In addition, specifically, the reflective mask blank 100 having an absorber film having a small refractive index (n), a high extinction coefficient (k), and good processing characteristics can be obtained.

The reflective mask blank 100 includes a configuration in which the conductive back film 5 is not formed. Furthermore, the reflective mask blank 100 includes a configuration of a mask blank with a resist film in which a resist film 11 is formed on an etching mask film.

In the present specification, for example, the description of “the multilayer reflective film 2 on the substrate 1” means that the multilayer reflective film 2 is disposed in contact with a surface of the substrate 1 and also means that another film is disposed between the substrate 1 and the multilayer reflective film 2. The same applies to other films. In addition, in the present specification, for example, the expression “a film A is disposed on a film B in contact with the film B” means that the film A and the film B are disposed in direct contact with each other without another film interposed between the film A and the film B.

Hereinafter, each configuration of the reflective mask blank 100 will be specifically described.

<<Substrate 1>>

As the substrate 1, a material having a low thermal expansion coefficient in a range of 0±5 ppb/° C. is preferably used in order to prevent distortion of an absorber pattern 4a due to heat at the time of exposure to EUV light. As a material having a low thermal expansion coefficient within this range, for example, SiO₂—TiO₂-based glass or multicomponent-based glass ceramic can be used.

The first main surface of the substrate 1 on a side on which a transfer pattern (an absorber pattern 4a obtained by patterning an absorber film 4 described later corresponds to the transfer pattern) is formed has been subjected to a surface treatment so as to have high flatness from a viewpoint of obtaining at least pattern transfer accuracy and position accuracy. In a case of EUV exposure, flatness in an area of 132 mm×132 mm of the main surface on the side of the substrate 1 on which the transfer pattern is formed is preferably 0.1 μm or less, more preferably 0.05 μm or less, and particularly preferably 0.03 μm or less. In addition, the second main surface on a side opposite to the side on which the absorber film 4 is formed is a surface to be electrostatically chucked at the time of setting on an exposure apparatus, and in an area of 142 mm×142 mm of the second main surface, flatness is preferably 0.1 μm or less, more preferably 0.05 μm or less, and particularly preferably 0.03 μm or less.

In addition, high surface smoothness of the substrate 1 is also an extremely important item. Surface roughness of the first main surface of the substrate 1 on which the transfer pattern (absorber pattern 4a) is formed is preferably 0.1 nm or less in terms of root mean square roughness (RMS). Note that the surface smoothness can be measured with an atomic force microscope.

Furthermore, the substrate 1 has preferably high rigidity in order to prevent deformation due to film stress of a film (such as the multilayer reflective film 2) formed on the substrate 1. In particular, the substrate 10 preferably has a high Young's modulus of 65 GPa or more.

<<Multilayer Reflective Film 2>>

The multilayer reflective film 2 imparts a function that reflects EUV light in a reflective mask 200. The multilayer reflective film 2 has a structure of a multilayer film in which layers mainly containing elements having different refractive indexes are periodically layered.

Generally, as the multilayer reflective film 2, there is used a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. The multilayer film may be formed by counting, as one period, a stack of a high refractive index layer and a low refractive index layer in which the high refractive index layer and the low refractive index layer are layered in this order from the substrate 1 and then by building up the stack for a plurality of periods. Additionally, the multilayer film may be formed by counting, as one period, a stack of a low refractive index layer and a high refractive index layer in which the low refractive index layer and the high refractive index layer are layered in this order from the substrate 1 and by building up the stack for a plurality of periods. Note that a layer of the outermost surface of the multilayer reflective film 2, that is, a surface layer of the multilayer reflective film 2 on a side opposite to the substrate 1 is preferably a high refractive index layer. In the multilayer film described above, when a stack of a high refractive index layer and a low refractive index layer in which the high refractive index layer and the low refractive index layer are layered in this order from the substrate 1 is counted as one period and the stacks are built up for a plurality of periods, the uppermost layer is the low refractive index layer. In this case, when the low refractive index layer constitutes the outermost surface of the multilayer reflective film 2, the low refractive index layer is easily oxidized and the reflectance of the reflective mask 200 is therefore reduced. Therefore, it is preferable to further form a high refractive index layer on the low refractive index layer that is the uppermost layer to form the multilayer reflective film 2. Meanwhile, in the multilayer film described above, when a stack of a low refractive index layer and a high refractive index layer in which the low refractive index layer and the high refractive index layer are layered in this order from the substrate 1 side is counted as one period and the stacks are built up for a plurality of periods, the uppermost layer is the high refractive index layer, which is good as it is.

In the present embodiment, a layer containing silicon (Si) is adopted as the high refractive index layer. As a material including Si, a Si compound including boron (B), carbon (C), nitrogen (N), and oxygen (O) in Si may be used in addition to Si alone. By using the layer containing Si as the high refractive index layer, the reflective mask 200 for EUV lithography having an excellent EUV light reflectance can be obtained. In addition, in the present embodiment, a glass substrate is preferably used as the substrate 1. Si also has excellent adhesion to the glass substrate. In addition, as the low refractive index layer, a metal alone selected from molybdenum (Mo), ruthenium (Ru), rhodium (Rh), and platinum (Pt), or an alloy thereof is used. For example, as the multilayer reflective film 2 for EUV light having a wavelength of 13 nm to 14 nm, a Mo/Si periodic layered film in which a Mo film and a Si film are alternately layered for about 40 to 60 periods is preferably used. Note that a high refractive index layer that is the uppermost layer of the multilayer reflective film 2 may be made of silicon (Si), and a silicon oxide layer containing silicon and oxygen may be formed between the uppermost layer (Si) and the Ru-based protective film 3. This makes it possible to improve mask cleaning resistance.

The reflectance of such a multilayer reflective film 2 alone is usually 65% or more, and an upper limit thereof is usually 73%. Note that the film thickness and period of each constituent layer of the multilayer reflective film 2 only need to be appropriately selected according to an exposure wavelength and are selected so as to satisfy the Bragg reflection law. In the multilayer reflective film 2, there are a plurality of high refractive index layers and a plurality of low refractive index layers. The film thicknesses of the high refractive index layers do not have to be the same, and the film thicknesses of the low refractive index layers do not have to be the same. In addition, the film thickness of the Si layer on the outermost surface of the multilayer reflective film 2 can be adjusted within a range that does not lower the reflectance. The film thickness of the Si (high refractive index layer) of the outermost surface can be 3 nm to 10 nm.

A method of forming the multilayer reflective film 2 is publicly known in this technical field. For example, the multilayer reflective film 2 can be formed by forming each layer in the multilayer reflective film 2 by an ion beam sputtering method. In the case of the Mo/Si periodic multilayer film described above, first, a Si film having a thickness of about 4 nm is formed on the substrate 1 using a Si target by, for example, an ion beam sputtering method. Thereafter, a Mo film having a thickness of about 3 nm is formed using a Mo target. This stack of a Si film and a Mo film is counted as one period and the stacks are build up for 40 to 60 periods to form the multilayer reflective film 2 (the layer on the outermost surface is a Si layer). In addition, when the multilayer reflective film 2 is formed, the multilayer reflective film 2 is preferably formed by supplying krypton (Kr) ion particles from an ion source and performing ion beam sputtering. Note that the multilayer reflective film 2 preferably has about 40 periods from viewpoints of improvement in reflectance due to an increase in the number of stacking periods, reduction in throughput due to an increase in the number of steps, and the like. Note the number of stacking periods of the multilayer reflective film 2 is not limited to 40 periods, and may be, for example, 60 periods. In the case of 60 periods, the number of steps is larger than the number of steps in the case of 40 periods, but reflectance for EUV light can be increased.

<<Protective Film 3>>

The reflective mask blank 100 of the present embodiment preferably includes the protective film 3 between the multilayer reflective film 2 and the absorber film 4. The protective film 3 is formed on the multilayer reflective film 2, and it is thereby possible to suppress damage to a surface of the multilayer reflective film 2 when the reflective mask 200 (EUV mask) is manufactured using the reflective mask blank 100. Therefore, by the presence of the protective film 3, a reflectance characteristic for EUV light is improved.

The protective film 3 is formed on the multilayer reflective film 2 in order to protect the multilayer reflective film 2 from dry etching and cleaning in a step of manufacturing the reflective mask 200 to be described later. Additionally, the protective film 3 also serves to protect the multilayer reflective film 2 when a black defect of the absorber pattern 4a is repaired using an electron beam (EB). The protective film 3 is made of a material having resistance to an etchant, a cleaning liquid, and the like. FIG. 1 illustrates a case where the protective film 3 has one layer, but the protective film 3 can have a stack of three or more layers. For example, the protective film 3 can be one in which a lowermost layer and an uppermost layer are layers containing the substance containing Ru, and a metal or an alloy other than Ru is interposed between the lowermost layer and the uppermost layer. The protective film 3 can contain, for example, a material containing ruthenium as a main component. Specifically, the material of the protective film 3 can be Ru metal alone. In addition, the material of the protective film 3 can be a Ru alloy containing Ru and at least one metal selected from titanium (Ti), niobium (Nb), rhodium (Rh), molybdenum (Mo), zirconium (Zr), yttrium (Y), boron (B), lanthanum (La), cobalt (Co), rhenium (Re), and the like. In addition, the Ru metal alone or the Ru alloy can further contain nitrogen. Such a protective film 3 is particularly effective when the absorber film 4 (or a buffer layer 42 described later) is patterned by dry etching using a fluorine-based gas (F-based gas) or a chlorine-based gas (Cl-based gas) not containing oxygen as an etching gas. The protective film 3 is preferably made of a material having an etching selective ratio of 1.5 or more, preferably 3 or more, the etching selective ratio being an etching selective ratio of the absorber film 4 to the protective film 3 in dry etching using these etching gases (etching rate of the absorber film 4/etching rate of the protective film 3).

As the fluorine-based gas, gases such as CF₄, CHF₃, C₂F₆, C₃F₆, C₄F₆, C₄F₈, CH₂F₂, CH₃F, C₃F₈, SF₆, and/or F₂ can be used. As the chlorine-based gas, gases such as C₁₂, SiCl₄, CHCl₃, CCl₄, and/or BCl₃ can be used. In addition, a mixed gas containing a fluorine-based gas and/or a chlorine-based gas and O₂ at a predetermined ratio can be used. These etching gases can each further contain an inert gas such as He and/or Ar, if necessary.

In a case where a Ru alloy is used as the material of the protective film 3, the content of Ru in the Ru alloy is 50 atom % or more and less than 100 atom %, preferably atom % or more and less than 100 atom %, and more preferably 95 atom % or more and less than 100 atom %. In particular, when the content of Ru in the Ru alloy is 95 atom % or more and less than 100 atom %, the reflectance for EUV light can be ensured sufficiently while diffusion of an element (silicon) constituting the multilayer reflective film 2 to the protective film 3 is suppressed. Furthermore, this protective film 3 can have functions as the protective film 3, that is, mask cleaning resistance, an etching stopper function when the absorber film 4 is etched, and a function of preventing the multilayer reflective film 2 from changing over time.

The material of the protective film 3 can be a material containing silicon (Si). The material containing silicon (Si) contains, for example, at least one material selected from silicon (Si), a silicon oxide (SiₓO_{y} (x and y are integers of 1 or more) such as SiO, Sift, or Si₃O₂), a silicon nitride (SiₓN_{y} (x and y are integers of 1 or more) such as SiN or Si₃N₄), and a silicon oxynitride (SiₓO_{y}N_{z} (x, y, and z are integers of 1 or more) such as SiON). Such a protective film 3 is particularly effective when a buffer layer 42 described later is disposed as a lower layer of the absorber film 4, and the buffer layer is patterned by dry etching with a chlorine-based gas (Cl-based gas) containing an oxygen gas. The protective film 3 is preferably made of a material having an etching selective ratio of 1.5 or more, preferably 3 or more, the etching selective ratio being an etching selective ratio of the absorber film 4 to the protective film 3 in dry etching using a chlorine-based gas containing an oxygen gas (etching rate of the absorber film 4/etching rate of the protective film 3).

In the reflective mask blank 100 of the present embodiment, the protective film 3 is preferably made of a material containing ruthenium (Ru) or silicon (Si). When the protective film 3 is made of a material containing ruthenium (Ru) (for example, Ru alone or an Ru alloy), damage to a surface of the multilayer reflective film 2 can be effectively suppressed. In addition, when the protective film 3 is made of a material containing silicon (Si), the degree of freedom in selecting a material of the absorber film 4 can be increased.

In EUV lithography, since there are few substances that are transparent to exposure light, it is not technically easy to achieve an EUV pellicle that prevents foreign matters from being attached to a mask pattern surface. For this reason, pellicle-less operation without using a pellicle has been the mainstream. In addition, in EUV lithography, exposure contamination such as carbon film deposition on a mask or an oxide film growth due to EUV exposure occurs. Therefore, it is necessary to frequently clean and remove foreign matters and contamination on the EUV reflective mask 200 at a stage where the EUV reflective mask 200 is used for manufacturing a semiconductor device. For this reason, the EUV reflective mask 200 is required to have extraordinary mask cleaning resistance as compared with a transmission type mask for optical lithography. When the Ru-based protective film 3 containing Ti is used, cleaning resistance to a cleaning liquid such as sulfuric acid, sulfuric acid/hydrogen peroxide mixture (SPM), ammonia, ammonia/hydrogen peroxide mixture (APM), OH radical cleaning water, or ozone water having a concentration of 10 ppm or less is particularly high, and requirement for mask cleaning resistance can be satisfied.

The film thickness of such a protective film 3 containing ruthenium (Ru) or an alloy thereof, silicon (Si), or the like is not particularly limited as long as a function as the protective film 3 can be performed. From the viewpoint of the reflectance for EUV light, the film thickness of the protective film 3 is preferably 1.0 nm to 8.0 nm and more preferably 1.5 nm to 6.0 nm.

As a method for forming the protective film 3, it is possible to adopt a film forming method similar to a publicly known one without any particular limitation. Specific examples thereof include a sputtering method and an ion beam sputtering method.

<<Absorber Film 4>>

In the reflective mask blank 100 of the present embodiment, the absorber film 4 that absorbs EUV light is formed on the multilayer reflective film 2 or the protective film 3. The absorber film 4 has a function of absorbing EUV light. The absorber film 4 may be the absorber film 4 for the purpose of absorbing EUV light, or may be the absorber film 4 having a phase shift function in consideration of a phase difference of EUV light.

First, an absorber film 4 used for a reflective mask blank 100 of a first embodiment will be described. The absorber film 4 of the reflective mask blank 100 of the present embodiment (first embodiment) contains iridium (Ir) and an additive element. First, a reason why the absorber film 4 of the present embodiment contains iridium (Ir) will be described.

In order to achieve high integration and low cost of a semiconductor device, it is necessary to form a transfer pattern having a fine pattern shape on a transferred substrate with a high throughput in an EUV exposure step. In order to transfer a fine pattern shape, it is necessary to suppress the shadowing effect. For this purpose, the film thickness of the absorber pattern 4a needs to be thinner than that of a conventional one. In addition, in order to form the transfer pattern with a high throughput, it is necessary to increase a contrast in the EUV exposure step.

In order to satisfy the above-described requirements, it is necessary to appropriately select the material of the absorber film 4. As a guideline for selecting the material of the absorber film 4, an “evaluation function” is used. The “evaluation function” is a product of a normalized image log slope (NILS) and a threshold of a light intensity for photosensitizing a predetermined resist. Note that a “normalized evaluation function” obtained by normalizing the “evaluation function” can be used as the guideline for selecting the material of the absorber film 4.

The normalized image log slope (NILS) refers to one expressed by the following formula 1. Note that, in formula 1, W (unit: nm) represents a pattern size, and I represents a light intensity. “I=I_{threshold}” indicates that a differential is a predetermined differential value at a place corresponding to an edge of a pattern of the pattern size W (that is, a place where the light intensity is a threshold described later). Note that, in the present specification, the normalized image log slope may be simply referred to as “NILS”.

$$[ Mathematical Formula 1 ]$$

$${N I L S = W \frac{d ln ( I )}{dx} \vert}_{I = {I}_{threshold}} \qquad ( Formula 1 )$$

In the present specification, the “normalized image log slope (NILS)” indicates the magnitude of a slope when a horizontal axis represents a position and a vertical axis represents a logarithm of a light intensity of exposure light. That is, the higher the NILS, the higher the contrast. In EUV lithography, a predetermined transfer pattern is transferred onto a resist layer on a transferred substrate. A resist of the resist layer is photosensitized according to a dose of exposure light (obtained by multiplying a light intensity by time). Therefore, when the exposed resist is developed, the slope of the shape of the pattern edge portion of the transfer pattern is larger as the contrast (NILS) is higher. In a case where the slope of the shape of the pattern edge portion is large (steep), dependence of the position of the pattern edge on the dose of exposure light is small. Therefore, even when the dose changes, a change in the shape of the transfer pattern is small. From the above, the normalized image log slope (NILS) is preferably high in order to obtain a fine and highly accurate transfer pattern. In addition, it can be said that a transfer pattern having a finer pattern shape can be formed on a transferred substrate as the normalized image log slope (NILS) is higher. Note that the transfer pattern formed on the transferred substrate may be referred to as a resist transfer pattern.

In the present specification, the “threshold” of a light intensity for photosensitizing a predetermined resist refers to a light intensity at which the resist is photosensitized at a predetermined half pitch (also simply referred to as “hp” in the present specification) during EUV exposure for forming a resist transfer pattern of a line-and-space pattern (also simply referred to as “L/S” in the present specification) of a predetermined hp. For example, in a graph (aerial image) having a shape in which a vertical axis represents a light intensity and a horizontal axis represents a hp of L/S, the “threshold” refers to a light intensity at which the resist is photosensitized at a predetermined hp. Specifically, for example, in a case where a negative photosensitive material is used as the resist, the threshold means a light intensity at which the negative photosensitive material becomes completely insoluble when development is performed after exposure at a predetermined light intensity. As the threshold is higher, the dose of exposure light at the time of EUV exposure is smaller, and therefore the throughput of the EUV exposure step is higher. Therefore, in order to increase the throughput of the EUV exposure step, the threshold is preferably high.

In the present specification, the “evaluation function” is a product of a normalized image log slope (NILS) and a threshold of a light intensity for photosensitizing a predetermined resist. It can be said that as a value of the evaluation function of the reflective mask 200 having the absorber pattern 4a of a predetermined material is larger, a transfer pattern (resist transfer pattern) formed on a transferred substrate and having a fine pattern shape can be formed more reliably, and the EUV exposure can be performed with a higher throughput.

In the present specification, the “normalized evaluation function” means a ratio of a value of the evaluation function obtained by normalizing a value of the evaluation function of a film to be compared when a value of the evaluation function of the reflective mask 200 using a pattern (reference film pattern) of a film (referred to as a “reference film” in the present specification) having a refractive index (n) of 0.95 and an extinction coefficient (k) of 0.03 for EUV light having a wavelength of 13.5 nm as the absorber pattern 4a is defined as 1.

The values of the “evaluation function” and the “normalized evaluation function” can be obtained by simulation. Therefore, in a case of exposure with light having a wavelength of 13.5 nm, when the refractive index (n) and the extinction coefficient (k) of the absorber film 4 (absorber pattern 4a) of the reflective mask 200 were changed, a value of the normalized evaluation function was determined by simulation. Note that the reflective mask 200 used for the simulation has a structure in which the multilayer reflective film 2 made of Mo and Si (a layer obtained by building up a pair of a 4.2 nm Si film and a 2.8 nm Mo film for 40 periods) and the protective film 3 of a RuNb film (n=0.9016, k=0.0131, film thickness 3.5 nm) are formed on the substrate 1 (SiO₂—TiO₂-based glass substrate), and the absorber pattern 4a is formed on the protective film 3. The film thickness of the absorber pattern 4a was optimized so as to have the highest value of the evaluation function.

FIG. 4 illustrates a value of the normalized evaluation function obtained by simulation (simulation #1a) in a case where the absorber pattern 4a is a vertical line-and-space (L/S) pattern of hp 16 nm for the reflective mask 200 (the protective film 3 is a RuNb film) of the simulation described above. FIG. 4 is a diagram illustrating a distribution of values of the normalized evaluation function when predetermined incident light is emitted to the absorber patterns 4a having different refractive indexes (n) and extinction coefficients (k) in the reflective mask 200 of the simulation #1a. In the simulation illustrated in FIG. 4, a large number of simulations were performed assuming the absorber films 4 having a large number of combinations of the refractive index (n) and the extinction coefficient (k) in the range illustrated in FIG. 4. FIG. 4 illustrates a value of the normalized evaluation function in gray scale.

A simulation similar to the simulation #1a whose results are illustrated in FIG. 4 was performed for a case where the absorber pattern 4a was a horizontal L/S pattern (Horizontal L/S, hp=16 nm) (simulation #2a) and a case where the absorber pattern 4a was a contact hole pattern (Contact Hole, diameter 24 nm) (simulation #3a). In addition, the material of the protective film 3 of the simulation #1a was changed to a RuRh film (n=0.8898, k=0.0155, film thickness 3.5 nm), and simulations #1b, #2b, and #3b were performed similarly to the simulations #1a, #2a, and #3a.

FIG. 5 illustrates a distribution of values of the normalized evaluation function obtained by combining all the simulations #1a to #3a and #1b to #3b. FIG. 5 is a diagram illustrating a distribution obtained by binarization into a case where the values of the normalized evaluation functions are all 1.015 or more (white) and other cases (black) in all the simulations.

From the results of the above simulations, it can be understood that, in the distribution of the refractive index (n) and the extinction coefficient (k) of the absorber pattern 4a (absorber film 4), a region in which the values of the normalized evaluation functions are all 1.015 or more is a region indicated as white in FIG. 5. A material of a single substance belonging to the region in which the values of the normalized evaluation functions are all 1.015 or more is Ag, Co, Pt, Au, Fe, Pd, Ir, W, Cr, Rh, Ru, or the like. Therefore, when the absorber film 4 is formed using these materials, it can be said that a transfer pattern having a finer pattern shape can be more reliably formed on the transferred substrate and EUV exposure can be performed with higher throughput as compared with a conventional absorber film 4 using a TaBN film, a TaN film, or the like as a material.

The present inventor has focused on the fact that iridium (Ir) is included in the region in which the values of the normalized evaluation function are all 1.015 or more. Note that iridium (Ir) has a low etching rate and poor processability. Therefore, when the absorber film 4 made only of Ir is used, there is a problem that it is not easy to form the absorber pattern 4a. Therefore, the present inventor has found that the problem of the processability of Ir can be solved by using a material containing Ir and a predetermined additive element as the material of the absorber film 4 of the reflective mask blank 100. Therefore, by using the reflective mask blank 100 having the predetermined absorber film 4 of the present embodiment (absorber film 4 containing Ir and a predetermined additive element), it is possible to manufacture the reflective mask 200 that makes it possible to form a transfer pattern having a fine pattern shape on a transferred substrate and that has a transfer pattern capable of performing EUV exposure with a high throughput.

In the reflective mask blank 100 of the present embodiment, the content of iridium (Ir) in the absorber film 4 is more than 50 atom %, preferably 60 atom % or more, and more preferably 70 atom % or more. Iridium (Ir) has a refractive index of 0.905 and an extinction coefficient of 0.044 for EUV light having a wavelength of 13.5 nm. That is, the extinction coefficient of iridium (Ir) is higher than that of tantalum (Ta) or the like, and the refractive index of iridium (Ir) is lower than that of tantalum (Ta) or the like. Therefore, when the content of iridium (Ir) in the absorber film 4 is relatively high, it is possible to obtain the reflective mask 200 having the absorber pattern 4a with a high contrast and a thin film thickness. As a result, the shadowing effect at the time of exposure can be reduced.

When the absorber film 4 made only of iridium (Ir) is used, it is not easy to form the absorber pattern 4a by etching. Therefore, the content (upper limit) of iridium (Ir) in the absorber film 4 is preferably 90 atom % or less, and more preferably 80 atom % or less.

The absorber film 4 of the present embodiment contains an additive element. The additive element is at least one selected from boron (B), silicon (Si), phosphorus (P), titanium (Ti), germanium (Ge), arsenic (As), selenium (Se), niobium (Nb), molybdenum (Mo), ruthenium (Ru), and tantalum (Ta). When the additive elements contained in the absorber film 4 are these elements, an etching rate of the absorber film 4 with respect to an appropriate etching gas (for example, a fluorine-based etching gas) can be improved, and processability of the absorber film 4 can be improved.

The additive element contained in the absorber film 4 is preferably at least one selected from tantalum (Ta), molybdenum (Mo), niobium (Nb), and boron (B). When the additive elements contained in the absorber film 4 are these elements, the etching rate of the absorber film 4 with respect to the fluorine-based etching gas can be further improved.

In the reflective mask blank 100 of the present embodiment, the additive element contained in the absorber film 4 more preferably contains tantalum (Ta). Since iridium (Ir) is a material having compressive stress, it is preferable to select tantalum (Ta) having tensile stress as the additive element. Therefore, by inclusion of tantalum (Ta) in the absorber film 4, it is possible to obtain the absorber film 4 with a good balance in stress. In addition, in recent years, tantalum (Ta) has been often used as a material of the absorber film 4 of the reflective mask blank 100, and has high reliability. In addition, the absorber film 4 containing iridium (Ir) and tantalum (Ta) can be easily etched by using a fluorine-based etching gas, and therefore has good processability. Therefore, by inclusion of tantalum (Ta) in the absorber film 4, the reflective mask blank 100 having high reliability and good processability can be obtained.

In the reflective mask blank 100 of the present embodiment, when the additive element contains tantalum (Ta), the content of tantalum (Ta) in the absorber film 4 is preferably 2 atom % or more, and more preferably 10 atom % or more. In addition, the content of tantalum (Ta) is preferably 30 atom % or less, and more preferably 20 atom % or less. When the content of tantalum (Ta) in the absorber film 4 is 2 to 30 atom %, the absorber film 4 having an excellent balance among optical characteristics, processing characteristics, and stress can be obtained.

When the additive element contained in the absorber film 4 contains boron (B), the content of B in the absorber film 4 is preferably 2 atom % or more, and more preferably 5 atom % or more. In addition, the content of B is preferably 25 atom % or less, and more preferably 20 atom % or less. When the content of B in the absorber film 4 is within the above range, the absorber film 4 having excellent balance among optical characteristics, processing characteristics, and stress can be obtained.

When the additive element contained in the absorber film 4 contains silicon (Si), the content of Si in the absorber film 4 is preferably 2 atom % or more, and more preferably 5 atom % or more. In addition, the content of Si is preferably 25 atom % or less, and more preferably 20 atom % or less. When the content of Si in the absorber film 4 is within the above range, the absorber film 4 having excellent balance among optical characteristics, processing characteristics, and stress can be obtained.

When the additive element contained in the absorber film 4 contains phosphorus (P), the content of P in the absorber film 4 is preferably 2 atom % or more, and more preferably 5 atom % or more. In addition, the content of P is preferably 20 atom % or less, and more preferably 10 atom % or less. When the content of P in the absorber film 4 is within the above range, the absorber film 4 having excellent balance among optical characteristics, processing characteristics, and stress can be obtained.

When the additive element contained in the absorber film 4 contains titanium (Ti), the content of Ti in the absorber film 4 is preferably 2 atom % or more, and more preferably 10 atom % or more. In addition, the content of Ti is preferably 30 atom % or less, and more preferably 20 atom % or less. When the content of Ti in the absorber film 4 is within the above range, the absorber film 4 having excellent balance among optical characteristics, processing characteristics, and stress can be obtained.

When the additive element contained in the absorber film 4 contains germanium (Ge), the content of Ge in the absorber film 4 is preferably 2 atom % or more, and more preferably 5 atom % or more. In addition, the content of Ge is preferably 30 atom % or less, and more preferably 20 atom % or less. When the content of Ge in the absorber film 4 is within the above range, the absorber film 4 having excellent balance among optical characteristics, processing characteristics, and stress can be obtained.

When the additive element contained in the absorber film 4 contains arsenic (As), the content of As in the absorber film 4 is preferably 2 atom % or more, and more preferably 5 atom % or more. In addition, the content of As is preferably 30 atom % or less, and more preferably 20 atom % or less. When the content of As in the absorber film 4 is within the above range, the absorber film 4 having excellent balance among optical characteristics, processing characteristics, and stress can be obtained.

When the additive element contained in the absorber film 4 contains selenium (Se), the content of Se in the absorber film 4 is preferably 2 atom % or more, and more preferably 5 atom % or more. In addition, the content of Se is preferably 30 atom % or less, and more preferably 20 atom % or less. When the content of Se in the absorber film 4 is within the above range, the absorber film 4 having excellent balance among optical characteristics, processing characteristics, and stress can be obtained.

When the additive element contained in the absorber film 4 contains niobium (Nb), the content of Nb in the absorber film 4 is preferably 2 atom % or more, and more preferably 5 atom % or more. In addition, the content of Nb is preferably 30 atom % or less, and more preferably 25 atom % or less. When the content of Nb in the absorber film 4 is within the above range, the absorber film 4 having excellent balance among optical characteristics, processing characteristics, and stress can be obtained.

When the additive element contained in the absorber film 4 contains molybdenum (Mo), the content of Mo in the absorber film 4 is preferably 2 atom % or more, and more preferably 5 atom % or more. In addition, the content of Mo is preferably 49 atom % or less, and more preferably 45 atom % or less. When the content of Mo in the absorber film 4 is within the above range, the absorber film 4 having excellent balance among optical characteristics, processing characteristics, and stress can be obtained.

When the additive element contained in the absorber film 4 contains ruthenium (Ru), the content of Ru in the absorber film 4 is preferably 2 atom % or more, and more preferably 5 atom % or more. In addition, the content of Ru is preferably 49 atom % or less, and more preferably 45 atom % or less. When the content of Ru in the absorber film 4 is within the above range, the absorber film 4 having excellent balance among optical characteristics, processing characteristics, and stress can be obtained.

In addition, in the reflective mask blank 100 of the present embodiment, the additive element contained in the absorber film 4 contains tantalum (Ta), and a content ratio between Ir and Ta (Ir:Ta) is preferably 4:1 to 22:1, and more preferably 6:1 to 15:1. When the content ratio between Ir and Ta is within a predetermined range, the absorber film 4 having excellent balance among optical characteristics, processing characteristics, and stress can be reliably obtained.

When the additive element contained in the absorber film 4 contains boron (B), a content ratio between Ir and B (Ir:B) is preferably 3:1 to 20:1, and more preferably 4:1 to 9:1. When the content ratio between Ir and B is within a predetermined range, the absorber film 4 having excellent balance among optical characteristics, processing characteristics, and stress can be reliably obtained.

When the additive element contained in the absorber film 4 contains silicon (Si), a content ratio between Ir and Si (Ir:Si) is preferably 3:1 to 20:1, and more preferably 4:1 to 9:1. When the content ratio between Ir and Si is within a predetermined range, the absorber film 4 having excellent balance among optical characteristics, processing characteristics, and stress can be reliably obtained.

When the additive element contained in the absorber film 4 contains phosphorus (P), a content ratio between Ir and P (Ir:P) is preferably 4:1 to 30:1, and more preferably 9:1 to 20:1. When the content ratio between Ir and P is within a predetermined range, the absorber film 4 having excellent balance among optical characteristics, processing characteristics, and stress can be reliably obtained.

When the additive element contained in the absorber film 4 contains titanium (Ti), a content ratio between Ir and Ti (Ir:Ti) is preferably 2.2:1 to 30:1, and more preferably 4:1 to 24:1. When the content ratio between Ir and Ti is within a predetermined range, the absorber film 4 having excellent balance among optical characteristics, processing characteristics, and stress can be reliably obtained.

When the additive element contained in the absorber film 4 contains germanium (Ge), a content ratio between Ir and Ge (Ir:Ge) is preferably 2.2:1 to 30:1, and more preferably 4:1 to 24:1. When the content ratio between Ir and Ge is within a predetermined range, the absorber film 4 having excellent balance among optical characteristics, processing characteristics, and stress can be reliably obtained.

When the additive element contained in the absorber film 4 contains arsenic (As), a content ratio between Ir and As (Ir:As) is preferably 2.2:1 to 30:1, and more preferably 4:1 to 24:1. When the content ratio between Ir and As is within a predetermined range, the absorber film 4 having excellent balance among optical characteristics, processing characteristics, and stress can be reliably obtained.

When the additive element contained in the absorber film 4 contains selenium (Se), a content ratio between Ir and Se (Ir:Se) is preferably 2.2:1 to 30:1, and more preferably 4:1 to 24:1. When the content ratio between Ir and Se is within a predetermined range, the absorber film 4 having excellent balance among optical characteristics, processing characteristics, and stress can be reliably obtained.

When the additive element contained in the absorber film 4 contains niobium (Nb), a content ratio between Ir and Nb (Ir:Nb) is preferably 2.2:1 to 30:1, and more preferably 4:1 to 24:1. When the content ratio between Ir and Nb is within a predetermined range, the absorber film 4 having excellent balance among optical characteristics, processing characteristics, and stress can be reliably obtained.

When the additive element contained in the absorber film 4 contains molybdenum (Mo), a content ratio between Ir and Mo (Ir:Mo) is preferably 1.2:1 to 9:1, and more preferably 1.5:1 to 4:1. When the content ratio between Ir and Mo is within a predetermined range, the absorber film 4 having excellent balance among optical characteristics, processing characteristics, and stress can be reliably obtained.

When the additive element contained in the absorber film 4 contains ruthenium (Ru), a content ratio between Ir and Ru (Ir:Ru) is preferably 1.2:1 to 9:1, and more preferably 1.5:1 to 4:1. When the content ratio between Ir and Ru is within a predetermined range, the absorber film 4 having excellent balance among optical characteristics, processing characteristics, and stress can be reliably obtained.

In the reflective mask blank 100 of the present embodiment, the absorber film 4 preferably further contains at least one selected from oxygen (O), nitrogen (N), and carbon (C). In addition, the content of oxygen (O), nitrogen (N), and/or carbon (C) is preferably 5 atom % or more, and more preferably 10 atom % or more. By further inclusion of a predetermined amount of oxygen (O), nitrogen (N), and/or carbon (C) in the absorber film 4, processability of the absorber film 4 by etching can be improved as compared with the absorber film 4 made of Ir alone.

Note that when the content of oxygen (O), nitrogen (N), and/or carbon (C) in the absorber film 4 is too large, the extinction coefficient (k) of the absorber film 4 may decrease. Therefore, the content of oxygen (O), nitrogen (N), and/or carbon (C) in the absorber film 4 is preferably 60 atom % or less, more preferably 50 atom % or less, and still more preferably 25 atom % or less.

The absorber film 4 of the reflective mask blank 100 of the present embodiment more preferably contains oxygen (O). In addition, the content of oxygen (O) in the absorber film 4 is preferably 5 atom % or more, and more preferably 10 atom % or more. An upper limit of the content of oxygen (O) in the absorber film 4 is preferably 60 atom % or less, more preferably 50 atom % or less, and still more preferably 25 atom % or less.

An IrTaO film (absorber film 4) containing oxygen (O) can be easily etched using a fluorine-based etching gas (for example, a mixed gas of a CF₄ gas and an oxygen gas). A flow rate ratio of the fluorine-based gas can be, for example, CF₄:O₂=90:10. Therefore, by inclusion of a predetermined amount of oxygen (O) in the absorber film 4, processability of the absorber film 4 by etching can be further improved. In addition, by inclusion of a predetermined amount of oxygen (O) in the absorber film 4, film stress of the absorber film 4 can be adjusted, and optical characteristics can be improved.

In addition, the refractive index of the material of the absorber film 4 is preferably within a range of 0.86 to 0.95, and the extinction coefficient of the material of the absorber film 4 is preferably within a range of 0.015 to 0.065. It is preferable to adjust a composition ratio between Ir and an additive element such that the refractive index and the extinction coefficient of the absorber film 4 fall within the above ranges.

As illustrated in FIG. 2, the absorber film 4 of the reflective mask blank 100 of the present embodiment can include a buffer layer 42 containing chromium (Cr) and an absorption layer 44 disposed on the buffer layer 42. In this case, the above-described material of the absorber film 4 can be used as a material of the absorption layer 44. That is, the absorption layer 44 can contain iridium (Ir) and an additive element.

The buffer layer 42 can be disposed when an etching selective ratio between a material of the absorption layer 44 (absorber film 4) and a material of the multilayer reflective film 2 or the protective film 3 is not high. By disposing the buffer layer 42, the absorber pattern 4a can be easily formed, and therefore the absorber pattern 4a can be thinned. In addition, the above-described material of the absorber film 4 (material containing iridium (Ir) and an additive element) can be used as a material of the absorption layer 44. At this time, a material of the buffer layer 42 preferably has an etching selective ratio of 1.5 or more with respect to the material of the absorption layer 44. By disposing the buffer layer 42, a range of selection of the materials of the absorption layer 44 and the protective film 3 can be expanded without reducing the effect of the present disclosure.

When the absorption layer 44 (for example, an IrTaO film) containing iridium (Ir) is etched, a fluorine-based etching gas (for example, a mixed gas of a CF₄ gas and an 02 gas) can be used. Meanwhile, in a case of etching with a fluorine-based etching gas containing oxygen, the protective film 3 (for example, a Ru-based protective film) may be damaged. By inclusion of the buffer layer 42 disposed between the absorption layer 44 and the protective film 3 in the absorber film 4 and inclusion of chromium (Cr) in the buffer layer 42, it is possible to avoid damage to the protective film 3 when the absorption layer 44 is etched.

In addition, the material of the buffer layer 42 can be a material containing chromium (Cr) and one or more elements selected from oxygen (O), nitrogen (N), carbon (C), boron (B), and hydrogen (H). Specific examples of the material of the buffer layer 42 include CrN, CrO, CrC, CrON, CrOC, CrCN, CrOCN, and the like. The buffer layer 42 containing chromium can be etched using a chlorine-based gas (for example, a mixed gas of a Cl₂ gas and an O₂ gas).

The film thickness of the buffer layer 42 is preferably ⅓ or less of the film thickness of the entire absorber film 4 (the absorption layer 44 and the buffer layer 42). The film thickness of the buffer layer 42 is preferably 10 nm or less, and more preferably 5 nm or less. Note that a lower limit of the film thickness of the buffer layer 42 can be 2 nm or more, and preferably 3 nm or more. In order to reduce the shadowing effect by reducing the film thickness of the absorber film 4 as much as possible, the film thickness of the buffer layer 42 is preferably a film thickness close to a minimum thickness for reducing an influence on the optical characteristics of the absorption layer 44 and exhibiting an effect as the buffer layer 42.

Next, an absorber film 4 used for a reflective mask blank 100 of a second embodiment will be described.

The reflective mask blank 100 of the second embodiment includes a substrate 1, a multilayer reflective film 2 on the substrate 1, and the absorber film 4 on the multilayer reflective film 2. The absorber film 4 includes an uppermost layer and other lower layers. The uppermost layer has a film thickness of 0.5 nm or more and less than 5 nm. The uppermost layer may contain iridium (Ir) alone or iridium (Ir) and the additive element. The additive element is at least one selected from boron (B), silicon (Si), phosphorus (P), titanium (Ti), germanium (Ge), arsenic (As), selenium (Se), niobium (Nb), molybdenum (Mo), ruthenium (Ru), and tantalum (Ta). In addition, the material of the absorber film 4 (material containing iridium (Ir) and an additive element) of the first embodiment can be used as a material of the uppermost layer.

The lower layer of the absorber film 4 of the second embodiment is not particularly limited as long as the lower layer is made of a material having a function of absorbing EUV light and having an etching selectivity with respect to the protective film 3. As such a material, at least one metal selected from palladium (Pd), silver (Ag), platinum (Pt), gold (Au), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals selected from these metals, or a compound thereof can be preferably used.

In addition, for the lower layer of the absorber film 4 of the second embodiment, at least one metal selected from Ag, Co, Pt, Au, Fe, Pd, W, Cr, Rh, and Ru belonging to a region in which a value of the above-described normalized evaluation function is 1.015 or more, an alloy containing two or more metals selected from these metals, or a compound thereof can be preferably used. The lower layer of the absorber film 4 contains preferably more than 50 atom %, more preferably 60 atom % or more of the metal or alloy.

The compound may contain the metal or alloy and oxygen (O), nitrogen (N), carbon (C), and/or boron (B).

In the first and second embodiments, in a case of the absorber film 4 intended to absorb EUV light, the film thickness is set such that a reflectance of EUV light to the absorber film 4 is 2% or less, preferably 1% or less.

In addition, the film thickness of each of the absorber films 4 of the reflective mask blanks 100 of the first and second embodiments is preferably 50 nm or less, and more preferably 45 nm or less. When the film thickness of the absorber film 4 of the reflective mask blank 100 is 50 nm or less, the shadowing effect at the time of EUV exposure can be reduced. Note that, in order to sufficiently absorb EUV light, a lower limit of the film thickness of the absorber film 4 can be 35 nm or more, and preferably nm or more.

The absorber films 4 of the first and second embodiments can be formed by a sputtering method (co-sputtering method) using an Ir target and a target of an additive element alone. Alternatively, the absorber film 4 can be formed by a sputtering method using an alloy target including Ir and an additive element.

<<Etching Mask Film>>

The reflective mask blank 100 of the present embodiment can include an etching mask film. The etching mask film has a film thickness of 0.5 nm or more and 14 nm or less.

By presence of an appropriate etching mask film, it is possible to obtain the reflective mask blank 100 capable of further reducing the shadowing effect of the reflective mask 200 and forming the fine and highly accurate absorber pattern 4a.

As illustrated in FIG. 1, then etching mask film is formed on the absorber film 4. As a material of the etching mask film, a material having a high etching selective ratio of the absorber film 4 to the etching mask film is used. Here, the “etching selective ratio of B to A” means a ratio of an etching rate of B that is a layer desired to be etched to an etching rate of A that is a layer not desired to be etched (layer to serve as a mask). Specifically, “etching selective ratio of B to A” is specified by a formula of “etching selective ratio of B to A=etching rate of B/etching rate of A”. In addition, the expression “high selective ratio” means that a value of the selective ratio defined above is large as compared with that of an object for comparison. An etching selective ratio of the absorption layer 44 to the etching mask film is preferably 1.5 or more, and more preferably 3 or more.

In the reflective mask blank 100 of the present embodiment, the material of the etching mask film is preferably a material containing chromium (Cr) and one or more elements selected from oxygen (O), nitrogen (N), carbon (C), boron (B), and hydrogen (H). Specific examples of the material of the etching mask film include CrN, CrO, CrC, CrON, CrOC, CrCN, CrOCN, and the like.

The film thickness of the etching mask film is 0.5 nm or more, preferably 1 nm or more, more preferably 2 nm or more, and still more preferably 3 nm or more from a viewpoint of obtaining a function as an etching mask that accurately forms a transfer pattern on the absorber film 4. In addition, the film thickness of the etching mask film is 14 nm or less, preferably 12 nm or less, and more preferably 10 nm or less from a viewpoint of reducing the film thickness of the resist film 11.

When the absorber film 4 includes two layers of the buffer layer 42 and the absorption layer 44, the etching mask film and the buffer layer 42 may be made of the same material. In addition, the etching mask film and the buffer layer 42 may be made of materials containing the same metal and having different composition ratios. When the etching mask film and the buffer layer 42 each contain chromium, the content of chromium in the etching mask film may be larger than the content of chromium in the buffer layer 42, and the film thickness of the etching mask film may be larger than the film thickness of the buffer layer 42. When the etching mask film and the buffer layer 42 each contain hydrogen, the content of hydrogen inf the etching mask film may be larger than the content of hydrogen in the buffer layer 42.

<<Resist Film 11>>

The reflective mask blank 100 of the present embodiment can include the resist film 11 on the etching mask film. The reflective mask blank 100 of the present embodiment also includes a form including the resist film 11. In the reflective mask blank 100 of the present embodiment, by selecting the absorber film 4 containing an appropriate material and/or having an appropriate film thickness and an etching gas, the resist film 11 can be thinned.

As a material of the resist film 11, for example, a chemically-amplified resist (CAR) can be used. By patterning the resist film 11 and etching the absorber film 4 (the buffer layer 42 and the absorption layer 44), the reflective mask 200 having a predetermined transfer pattern can be manufactured.

<<Conductive Back Film 5>>

The conductive back film 5 generally for electrostatic chuck is formed on the second main surface (back surface) side of the substrate 1 (surface opposite to a surface on which the multilayer reflective film 2 is formed). An electrical characteristic (sheet resistance) required for the conductive back film 5 for electrostatic chuck is usually 100Ω/□ (Ω/square) or less. As a method for forming the conductive back film 5, for example, a magnetron sputtering method and an ion beam sputtering method can be used. A target for sputtering can be selected from metal targets such as chromium (Cr) and tantalum (Ta), targets of alloys thereof, and the like.

A material containing chromium (Cr) for the conductive back film 5 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN, and the like.

As a material containing tantalum (Ta) for the conductive back film 5, Ta (tantalum), an alloy containing Ta, or a Ta compound containing either Ta or the alloy containing Ta and at least one of boron, nitrogen, oxygen, and carbon is preferably used. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like.

As a material containing tantalum (Ta) or chromium (Cr), the amount of nitrogen (N) present in a surface layer thereof is preferably small. Specifically, the nitrogen content in the surface layer of the conductive back film 5 of the material containing tantalum (Ta) or chromium (Cr) is preferably less than 5 atom %, and more preferably, the surface layer contains substantially no nitrogen. This is because in the conductive back film 5 of the material containing tantalum (Ta) or chromium (Cr), the lower the nitrogen content in the surface layer is, the higher wear resistance is.

The conductive back film 5 preferably contains a material containing tantalum and boron. The conductive back film 5 includes the material containing tantalum and boron, whereby the conductive back film 5 having wear resistance and chemical resistance can be obtained. In a case where the conductive back film 5 contains tantalum (Ta) and boron (B), B content is preferably 5 to 30 atom %. A ratio between Ta and B (Ta:B) in a sputtering target used for forming the conductive back film 5 is preferably from 95:5 to 70:30.

The film thickness of the conductive back film 5 is not particularly limited as long as a function of the conductive back film 5 for electrostatic chuck is satisfied. The film thickness of the conductive back film 5 is usually 10 nm to 200 nm. In addition, the conductive back film 5 further adjusts a stress on the second main surface side of the reflective mask blank 100. That is, the conductive back film 5 is adjusted such that the flat reflective mask blank 100 can be obtained in balance with a stress from various films formed on the first main surface side.

<Reflective Mask 200 and Method for Manufacturing the Same>

The present embodiment is the reflective mask 200 having the absorber pattern 4a in which the absorber film 4 of the reflective mask blank 100 described above is partnered. By using the reflective mask 200 of the present embodiment, a transfer pattern having a fine pattern shape can be formed on a transferred substrate, and EUV exposure to can be performed with a high throughput.

The absorber pattern 4a of the reflective mask 200 can absorb EUV light and reflect the EUV light at an opening of the absorber pattern 4a. Therefore, by irradiating the reflective mask 200 with EUV light using a predetermined optical system, a predetermined fine transfer pattern can be transferred onto a transferred object.

By patterning the absorber film 4 of the reflective mask blank 100 of the present embodiment, the reflective mask 200 can be manufactured. Here, only an outline description of a method for manufacturing the reflective mask 200 will be described, and later, details will be described in Examples with reference to the drawings.

The reflective mask blank 100 is prepared. The resist film 11 is formed on the absorber film 4 on the first main surface of the reflective mask blank 100 (this is not necessary in a case where the resist film 11 is included as the reflective mask blank 100). A desired pattern is drawn (exposed) on the resist film 11 and further developed and rinsed, whereby a predetermined resist pattern 11a is formed.

In the case of the reflective mask blank 100, by etching the absorber film 4 using the resist pattern 11a as a mask, the absorber pattern 4a is formed. The resist pattern 11a is peeled off by oxygen ashing or a wet treatment with hot sulfuric acid or the like. Finally, wet cleaning is performed using an acidic and/or alkaline aqueous solution.

Through the above steps, the reflective mask 200 of the present embodiment can be manufactured.

<Method for Manufacturing Semiconductor Device>

A method for manufacturing a semiconductor device of the present embodiment includes a step of setting the reflective mask 200 of the present embodiment in an exposure apparatus including an exposure light source that emits EUV light, and transferring a transfer pattern onto a resist layer formed on a transferred substrate. By the method for manufacturing a semiconductor device of the present embodiment, a transfer pattern having a fine pattern shape can be formed on a transferred substrate, and EUV exposure to can be performed with a high throughput.

According to the method for manufacturing a semiconductor device of the present embodiment, by using the reflective mask 200 of the present embodiment, a transfer pattern having a fine pattern shape can be formed on a transferred substrate. In addition, by using the reflective mask 200 of the present embodiment, EUV exposure can be performed with a high throughput.

By performing EUV exposure using the reflective mask 200 of the present embodiment, a desired pattern can be formed on a semiconductor substrate with high dimensional accuracy and a high throughput. Through various steps such as etching of a film to be processed, formation of an insulating film and a conductive film, introduction of a dopant, and annealing in addition to this lithography step, it is possible to manufacture a semiconductor device in which a desired electronic circuit is formed.

More specifically, an EUV exposure apparatus includes a laser plasma light source that generates EUV light, an illumination optical system, a mask stage system, a reduction projection optical system, a wafer stage system, vacuum equipment, and the like. The light source includes a debris trap function, a cut filter that cuts light having a long wavelength other than exposure light, equipment for vacuum differential pumping, and the like. The illumination optical system and the reduction projection optical system each include a reflection mirror. The reflective mask 200 for EUV exposure is electrostatically attracted by the conductive back film 5 formed on the second main surface (back surface) of the reflective mask 200 and is placed on a mask stage.

Light of the EUV light source is emitted to the reflective mask 200 through the illumination optical system at an angle tilted by 6° to 8° with respect to a vertical plane of the reflective mask 200. Reflected light from the reflective mask 200 with respect to the incident light is reflected (regularly reflected) in a direction opposite to the incident direction and at the same angle as the incident angle. The reflected light is guided to a reflective projection optical system usually having a reduction ratio of 1/4, and a resist layer on a wafer (semiconductor substrate) placed on a wafer stage is exposed to light. During this time, at least a place through which EUV light passes is evacuated. In addition, when this exposure is performed, mainstream exposure is scan exposure in which a mask stage and a wafer stage are synchronously scanned at a speed corresponding to a reduction ratio of the reduction projection optical system, and exposure is performed through a slit. Then, by developing the exposed resist of the resist layer, a resist transfer pattern can be formed on the semiconductor substrate. Then, by performing etching or the like using this resist transfer pattern as a mask, a predetermined wiring pattern can be formed, for example, on the semiconductor substrate. Through such an exposure step, a step of processing a film to be processed, a step of forming an insulating film and a conductive film, a dopant introduction step, an annealing step, and other necessary steps, the semiconductor device is manufactured.

### EXAMPLES

Hereinafter, Examples will be described with reference to the drawings. Note that in Examples, the same reference signs will be used for similar constituent elements, and the description thereof will be simplified or omitted.

### Experiments 1 to 7

In each of Experiments 1 to 7, a thin film (referred to as an “experimental absorber film”) corresponding to the absorber film 4 was manufactured. By evaluating the composition, film thickness, optical characteristics (refractive index (n) and extinction coefficient (k)), film stress, and etching characteristics of each of the experimental absorber films in Experiments 1 to 7, availability as an experimental absorber film was evaluated. Note that the experimental absorber films in Experiments 5 and 6 are the absorber films 4 used for the reflective mask blanks 100 in Examples 1 and 2, respectively.

Table 1 presents the materials and compositions of the experimental absorber films in Experiments 1 to 7. Note that the experimental absorber film in Experiment 7 is a thin film made only of Ir, and is an experimental absorber film for comparison with Experiments 1 to 6.

For Experiments 1 to 7, first, a substrate with a multilayer reflective film including the substrate 1, the multilayer reflective film 2, and the protective film 3 was manufactured. Note that the conductive back film 5 was formed on a back surface of the substrate 1. An experimental absorber film was formed so as to be disposed on the protective film 3 of the substrate with a multilayer reflective film in contact with the protective film 3. Therefore, the structure after formation of the experimental absorber film is similar to the reflective mask blank 100 illustrated in FIG. 1.

First, a substrate with a multilayer reflective film used for Experiments 1 to 7 will be described.

A SiO₂—TiO₂-based glass substrate that is a low thermal expansion glass substrate having 6025 size (about 152 mm×152 mm×6.35 mm) and having polished both main surfaces that are the first main surface and the second main surface was prepared as the substrate 1. The main surfaces were subjected to polishing including a rough polishing step, a precision polishing step, a local processing step, and a touch polishing step such that the main surfaces were flat and smooth.

Next, the conductive back film 5 formed of a CrN film was formed on the second main surface (back surface) of the SiO₂—TiO₂-based glass substrate 1 by a magnetron sputtering (reactive sputtering) method under the following conditions.

Conditions for forming conductive back film 5: a Cr target, a mixed gas atmosphere of Ar and N₂ (Ar: 90%, N: 10%), and a film thickness of 20 nm.

Next, the multilayer reflective film 2 was formed on the main surface (first main surface) of the substrate 1 on a side opposite to a side on which the conductive back film 5 was formed. The multilayer reflective film 2 formed on the substrate 1 was a periodic multilayer reflective film 2 containing Mo and Si in order to make the multilayer reflective film 2 suitable for EUV light having a wavelength of 13.5 nm. The multilayer reflective film 2 was formed using a Mo target and a Si target by alternately building up a Mo layer and a Si layer on the substrate 1 by an ion beam sputtering method in an Ar gas atmosphere. First, a Si film was formed to have a film thickness of 4.2 nm, and then a Mo film was formed to have a film thickness of 2.8 nm. This stack is counted as one period, the stack of a Si film and a Mo film was built up for periods in a similar manner, and finally, a Si film was formed to have a film thickness of 4.0 nm to form the multilayer reflective film 2.

Subsequently, the protective film 3 formed of a RuNb film was formed with a film thickness of 3.5 nm using a RuNb target in an Ar gas atmosphere by an ion beam sputtering method.

The substrate with a multilayer reflective film used in Experiments 1 to 7 was manufactured as described above.

Next, the buffer layer 42 made of CrON was formed on the protective film 3. Specifically, first, the buffer layer 42 formed of a CrON film was formed by a DC magnetron sputtering method. The CrON film was formed with a film thickness of 6 nm using a Cr target by reactive sputtering in a mixed gas atmosphere of an Ar gas, an O₂ gas, and a N₂ gas.

Thereafter, an experimental absorber film of a material illustrated in Table 1 was formed. Specifically, an experimental absorber film was formed by a DC magnetron sputtering method using a target and a sputtering gas illustrated in Table 2. Note that, in each of Experiments 5 and 6 containing oxygen (O), an experimental absorber film was formed by reactive sputtering using a sputtering gas containing an 02 gas.

The experimental absorber films formed as described above were subjected to the following measurement. Table 1 illustrates measurement results.

The elemental composition (atom %) of each of the experimental absorber films in Experiments 1 to 7 was measured by X-ray photoelectron spectroscopy (XPS method). Note that, in the following description, the elemental composition (atom %) of the thin film may be referred to as “composition” or “composition ratio”.

The film thickness of each of the experimental absorber films in Experiments 1 to 7 was measured by XRR (X-ray reflectance method).

The refractive index (n) and the extinction coefficient (k) of each of the experimental absorber films in Experiments 1 to 7 at a wavelength of 13.5 nm were measured by an EUV reflectometer.

The film stress in each of Experiments 1 to 7 was evaluated by measuring a flatness before the formation of the experimental absorber film and a flatness after the formation of the experimental absorber film with a flatness measuring device (UltraFlat 200 manufactured by Tropel Corporation) and comparing these values of flatness. Specifically, the film stress was evaluated by taking a difference between the flatness before the film formation of the experimental absorber film and the flatness after the film formation of the experimental absorber film. Table 1 illustrates measurement results of the difference in flatness.

Each of the etching rates in Experiments 1 to 7 was evaluated as follows. First, an etching rate was measured when each of the experimental absorber films in Experiments 1 to 7 was etched with a fluorine-based etching gas (a mixed gas of a CF₄ gas and an oxygen (O₂) gas, flow rate ratio CF₄:O₂=90:10). Next, an etching rate ratio (relative etching rate) when the etching rate in Experiment 7 (material: Ir) was defined as 1 was determined, and the etching rate was thereby evaluated, Table 1 illustrates the relative etching rate. Note that the experimental absorber film in Experiment 7 is a thin film made only of Ir, and is an experimental absorber film for comparison with Experiments 1 to 6.

As is apparent from Table 1, the extinction coefficient (k) of each of the experimental absorber films in Experiments 1 to 6 at a wavelength 13.5 nm was more than 0.03. Note that a TaBN film used as the absorber film 4 of Comparative Example 1 described later has an extinction coefficient (k) of 0.03 at a wavelength of 13.5 nm. At present, the TaBN film is one of materials generally used as the absorber film 4 of the reflective mask blank 100. Therefore, it can be said that the absorber film 4 having a high extinction coefficient (k) can be obtained by using each of the experimental absorber films having the compositions in Experiments 1 to 6 as the absorber film 4. Note that the experimental absorber film in Experiment 7 also has a high extinction coefficient (k) as in Experiments 1 to 6.

As is apparent from Table 1, the refractive index (n) of each of the experimental absorber films inf Experiments 1 to 6 at a wavelength of 13.5 nm was less than 0.95. Note that the TaBN film used as the absorber film 4 of Comparative Example 1 described later has a refractive index (n) of 0.95 at a wavelength of 13.5 nm. Therefore, it can be said that the absorber film 4 having a low refractive index (n) can be obtained by using each of the experimental absorber films having the compositions in Experiments 1 to 6 as the absorber film 4. Note that the experimental absorber film in Experiment 7 also has a low refractive index (n) as in Experiments 1 to 6.

As is apparent from Table 1, the difference in flatness of each of the experimental absorber films in Experiments 1 to 6 was 300 nm or less. Meanwhile, the difference in flatness of the experimental absorber film in Experiment 7 (material: Ir) was 811 nm. Therefore, it can be said that by using each of the experimental absorber films in Experiments 1 to 6 as the absorber film 4, it is possible to obtain the absorber film 4 capable of adjusting the film stress and suppressing deformation of the reflective mask blank 100.

As is apparent from Table 1, the relative etching rate of each of the experimental absorber films in Experiments 1 to 6 when the etching rate of the experimental absorber film (material: Ir) in Experiment 7 was defined as 1 was 1.3 to 1.8. Therefore, it can be said that by using each of the experimental absorber films in Experiments 1 to 6 as the absorber film 4, the absorber film 4 having a high etching rate and good processability can be obtained.

From the above results, it can be said that by using each of the experimental absorber films in Experiments 1 to 6 as the absorber film 4 of the reflective mask blank 100, it is possible to manufacture the reflective mask 200 that makes it possible to form a transfer pattern having a fine pattern shape on a transferred substrate and that has a transfer pattern capable of performing EUV exposure with a high throughput.

### Example 1

As Example 1, a thin film having the same composition and film thickness as those of the experimental absorber film in Experiment 5 was formed as the absorber film 4, and the reflective mask 200 was manufactured.

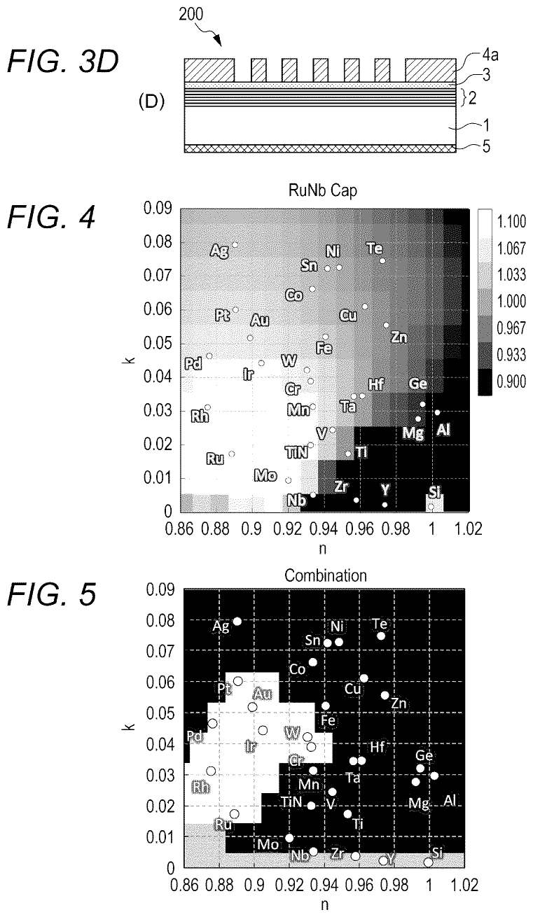

As illustrated in FIG. 2, the reflective mask blank 100 of Example 1 includes the conductive back film 5, the substrate 1, the multilayer reflective film 2, the protective film 3, and the absorber film 4 (the buffer layer 42 and the absorption layer 44). Note that, as illustrated in FIG. 3A, the structure in which the resist film 11 is formed on the absorber film 4 is also the reflective mask blank 100 of the present embodiment. FIGS. 3A to 3D are schematic main part cross-sectional views illustrating a process for manufacturing the reflective mask 200 from the reflective mask blank 100.

First, the reflective mask blank 100 of Example 1 will be described.

As in Experiments 1 to 7, a SiO₂—TiO₂-based glass substrate was prepared and used as the substrate 1. As in Experiments 1 to 7, polishing including a rough polishing step, a precision polishing step, a local processing step, and a touch polishing step was performed.

Next, as in Experiments 1 to 7, the conductive back film 5 formed of a CrN film was formed on the second main surface (back surface) of the SiO₂—TiO₂-based glass substrate 1 by a magnetron sputtering (reactive sputtering) method under the following conditions.

Conditions for forming conductive back film 5: a Cr target, a mixed gas atmosphere of Ar and N₂ (Ar: 90%, N: 10%), and a film thickness of 20 nm.

Next, as in Experiments 1 to 7, a Si layer (4.2 nm) and a Mo layer (2.8 nm) were alternately stacked for 40 periods on a main surface (first main surface) of the substrate 1 on a side opposite to the side where the conductive back film 5 was formed, and finally, a Si film was formed with a film thickness of 4.0 nm to form the multilayer reflective film 2.

Subsequently, as in Experiments 1 to 7, the protective film 3 formed of a RuNb film was formed with a film thickness of 3.5 nm.

Next, the buffer layer 42 made of CrON was formed on the protective film 3. Specifically, the CrON film was formed with a film thickness of 6 nm using a Cr target by reactive sputtering in a mixed gas atmosphere of an Ar gas, an 02 gas, and a N₂ gas. Thereafter, as in Experiment 5, the absorption layer 44 formed of an IrTaO film (composition ratio Ir:Ta:O=52:4:44, film thickness 40 nm) was formed by a DC magnetron sputtering method. Therefore, the reflective mask blank 100 of Example 1 includes the absorber film 4 including the buffer layer 42 of the CrON film and the absorption layer 44 of the IrTaO film.

As described above, the reflective mask blank 100 of Example 1 was manufactured.

The absorption layer 44 of the reflective mask blank 100 of Example 1 is the same thin film as the experimental absorber film in Experiment 5. Therefore, it can be said that by using the reflective mask blank 100 of Example 1, it is possible to manufacture the reflective mask 200 that makes it possible to form a transfer pattern having a fine pattern shape on a transferred substrate and that has a transfer pattern capable of performing EUV exposure with a high throughput.

Next, using the reflective mask blank 100 of Example 1, the reflective mask 200 of Example 1 was manufactured.

The resist film 11 was formed with a thickness of 80 nm on the absorber film 4 of the reflective mask blank 100 (FIG. 3A). A chemically amplified resist (CAR) was used for forming the resist film 11. A desired pattern was drawn (exposed) on this resist film 11, and further developed and rinsed to form a predetermined resist pattern 11a (FIG. 3B). Next, the absorption layer 44 (IrTaO film) was dry-etched with the resist pattern 11a as a mask using a mixed gas of a CF₄ gas and an O₂ gas (CF₄+O₂ gas). Subsequently, the CrON film (buffer layer 42) was dry-etched using a mixed gas of a Cl₂ gas and an O₂ gas (Cl₂+O₂ gas) to form the absorber pattern 4a (FIG. 3C).

Thereafter, the resist pattern 11a was peeled off by oxygen ashing (FIG. 3D). Finally, wet cleaning was performed with deionized water (DIW) to manufacture the reflective mask 200 of Example 1.

Note that a mask defect inspection can be performed as necessary after the wet cleaning, and a mask defect can be corrected appropriately.

The reflective mask 200 of Example 1 was set in an EUV scanner, and EUV exposure was performed on a wafer on which a film to be processed and a resist layer were formed on a semiconductor substrate. Then, the exposed resist of the resist layer was developed to form a resist transfer pattern on the semiconductor substrate on which the film to be processed was formed.

By forming the resist transfer pattern on the transferred substrate using the reflective mask 200 of Example 1, it has been confirmed that a transfer pattern having a fine pattern shape can be formed and EUV exposure can be performed with a high throughput.

This resist transfer pattern was transferred onto the film to be processed by etching, and through various steps such as formation of an insulating film and a conductive film, introduction of a dopant, and annealing, a semiconductor device having desired characteristics could be manufactured.

### Example 2

As Example 2, a thin film similar to that of Example 1 but having the same composition and film thickness as those of the experimental absorber film in Experiment 6 was formed as the absorption layer 44, and the reflective mask blank 100 and the reflective mask 200 were manufactured. That is, the reflective mask blank 100 and the reflective mask 200 of Example 2 are similar to those of Example 1 except that the absorption layer 44 (IrTaO film, film thickness 40 nm) has Ir:Ta:O=70:11:19 (composition ratio). Therefore, the reflective mask blank 100 of Example 2 includes the absorber film 4 including the buffer layer 42 of the CrON film and the absorption layer 44 of the IrTaO film.

The absorption layer 44 of the reflective mask blank 100 of Example 2 is the same thin film as the experimental absorber film in Experiment 6. Therefore, it can be said that by using the reflective mask blank 100 of Example 2, it is possible to manufacture a reflective mask 200 that makes it possible to form a transfer pattern having a fine pattern shape on a transferred substrate and that has a transfer pattern capable of performing EUV exposure with a high throughput.

In addition, by forming the resist transfer pattern on the transferred substrate using the reflective mask 200 of Example 2, it has been confirmed that a transfer pattern having a fine pattern shape can be formed and EUV exposure can be performed with a high throughput.

### Comparative Example 1

As Comparative Example 1, a TaBN film having a film thickness of 55 nm was formed as the absorber film 4, and the reflective mask blank 100 and the reflective mask 200 were manufactured, which is basically similar to Example 1. That is, the reflective mask blank 100 and the reflective mask 200 of Comparative Example 1 are similar to those of Example 1 except that the absorber film 4 is a TaBN film (Ta:B:N=75:12:13 (composition ratio)), has a film thickness of 55 nm, and does not include the buffer layer 42. Note that a reason why the film thickness of the TaBN film was set to 55 nm is that the extinction coefficient (k) of the TaBN film is lower than the extinction coefficient (k) of the absorber film 4 (IrTaO film) used in Examples 1 and 2.

Note that, when the absorber film 4 (TaBN film) was dry-etched for manufacturing the reflective mask 200 of Comparative Example 1, the TaBN film was dry-etched using a mixed gas of a CF₄ gas and a He gas (CF₄+He gas) to form the absorber pattern 4a (FIG. 3C).

The absorber film 4 of the reflective mask blank 100 of Comparative Example 1 is a TaBN film. The TaBN film had an extinction coefficient (k) of 0.03 and a refractive index (n) of 0.95 at a wavelength of 13.5 nm. Therefore, the extinction coefficient (k) of the absorber film 4 of Comparative Example 1 is lower than the extinction coefficients (k) of the absorber films 4 of Examples 1 and 2. In addition, the refractive index (n) of the absorber film 4 of Comparative Example 1 is higher than the refractive indexes (n) of the absorber films 4 of Examples 1 and 2. In addition, as illustrated in FIG. 5, it is apparent that a value of the normalized evaluation function when a thin film containing Ta is used as the absorber film 4 is higher than a value of the normalized evaluation function when a thin film containing Ir is used as the absorber film 4. Therefore, in the case of using the reflective mask blank 100 of Comparative Example 1, it is not easy to form a transfer pattern having a fine pattern shape on the transferred substrate as compared with the cases of Examples 1 and 2, and it cannot be said that EUV exposure can be performed with a high throughput.

In addition, by forming the resist transfer pattern on the transferred substrate using the reflective mask 200 of Comparative Example 1, a transfer pattern having a fine pattern shape could be formed to some extent. However, since the film thickness of the absorber film 4 of Comparative Example 1 was thicker than the film thicknesses of the absorber films 4 of Examples 1 and 2, a decrease in transfer accuracy, which is considered to be due to the shadowing effect, was observed.

TABLE 1

| | | | Other | Film | | | | Relative |
|---|---|---|---|---|---|---|---|---|
| | Thin film | Ir | than Ir | thickness | Refractive | Extinction | Difference in | etching |
| | material | (atom %) | (atom %) | (nm) | index (n) | coefficient (k) | flatness (nm) | rate |
| Experiment 1 | IrSi | 80 | Si = 20 | 48 | 0.926 | 0.033 | 10 | 1.8 |
| Experiment 2 | IrMo | 60 | Mo = 40 | 45 | 0.911 | 0.030 | 140 | 1.4 |
| Experiment 3 | IrRu | 70 | Ru = 30 | 45 | 0.889 | 0.035 | 203 | 1.3 |
| Experiment 4 | IrTa | 80 | Ta = 20 | 40 | 0.914 | 0.043 | 39 | 1.3 |
| Experiment 5 | IrTaO | 52 | Ta = 4 | 40 | 0.927 | 0.033 | 291 | 1.7 |
| (Example 1) | | | O = 44 | | | | | |
| Experiment 6 | IrTaO | 70 | Ta = 11 | 40 | 0.919 | 0.041 | 220 | 1.4 |
| (Example 2) | | | O = 19 | | | | | |
| Experiment 7 | Ir | 100 | — | 40 | 0.905 | 0.044 | 811 | 1 |

TABLE 2

| | Thin film | | |
|---|---|---|---|
| | material | Target | Sputtering gas |
| Experiment 1 | IrSi | IrSi alloy | Xe gas |
| Experiment 2 | IrMo | IrMo alloy | Xe gas |
| Experiment 3 | IrRu | IrRu alloy | Xe gas |
| Experiment 4 | IrTa | IrTa alloy | Xe gas |
| Experiment 5 | IrTaO | IrTa alloy | Mixed gas of Xe gas |
| | | | and O₂ gas |
| Experiment 6 | IrTaO | IrTa alloy | Mixed gas of Xe gas |
| | | | and O₂ gas |
| Experiment 7 | Ir | Ir | Xe gas |

### REFERENCE SIGNS LIST

1 Substrate
2 Multilayer reflective film
3 Protective film
4 Absorber film
4a Absorber pattern
5 Conductive back film
42 Buffer layer
44 Absorption layer
11 Resist film
11a Resist pattern
100 Reflective mask blank
200 Reflective mask

1. A reflective mask blank comprising: a substrate; a multilayer reflective film above the substrate; and an absorber film above the multilayer reflective film, wherein
the absorber film comprises iridium (Ir) and an additive element,
the additive element is at least one selected from boron (B), silicon (Si), phosphorus (P), titanium (Ti), germanium (Ge), arsenic (As), selenium (Se), niobium (Nb), molybdenum (Mo), ruthenium (Ru), and tantalum (Ta), and
a content of the iridium (Ir) in the absorber film is more than 50 atom %.

2. (canceled)

3. The reflective mask blank according to claim 1, wherein the additive element comprises tantalum (Ta), and a content of the tantalum (Ta) in the absorber film is 2 to 30 atom %.

4. The reflective mask blank according to claim 1, wherein the absorber film further comprises oxygen (O), and a content of the oxygen (O) is 5 atom % or more.

5. The reflective mask blank according to claim 1, wherein
the absorber film comprises a buffer layer and an absorption layer disposed on the buffer layer,
the buffer layer comprises chromium (Cr), and
the absorption layer comprises the iridium (Ir) and the additive element.

6. The reflective mask blank according to claim 5, wherein the absorber film has a film thickness of 50 nm or less, and
the buffer layer has a film thickness of 10 nm or less.

7. A reflective mask comprising: a substrate; a multilayer reflective film above the substrate; and an absorber film above the multilayer reflective film and having an absorber pattern, wherein
the absorber film comprises iridium (Ir) and an additive element,
the additive element is at least one selected from boron (B), silicon (Si), phosphorus (P), titanium (Ti), germanium (Ge), arsenic (As), selenium (Se), niobium (Nb), molybdenum (Mo), ruthenium (Ru), and tantalum (Ta), and
a content of the iridium (Ir) in the absorber film is more than 50 atom %.

8. (canceled)

9. (canceled)

10. The reflective mask blank according to claim 3, wherein the absorber film further comprises oxygen (O), and a content of the oxygen (O) is 5 atom % or more.

11. The reflective mask blank according to claim 1, wherein the additive element comprises tantalum (Ta), and a content ratio between Ir and Ta (Ir:Ta) is 4:1 to 22:1.

12. The reflective mask blank according to claim 11, wherein the absorber film further comprises oxygen (O), and a content of the oxygen (O) is 5 atom % or more.

13. The reflective mask according to claim 7, wherein the additive element comprises tantalum (Ta), and a content of the tantalum (Ta) in the absorber film is 2 to 30 atom %.

14. The reflective mask according to claim 7, wherein the absorber film further comprises oxygen (O), and a content of the oxygen (O) is 5 atom % or more.

15. The reflective mask according to claim 7, wherein
the absorber film comprises a buffer layer and an absorption layer disposed on the buffer layer,
the buffer layer comprises chromium (Cr), and
the absorption layer comprises the iridium (Ir) and the additive element.

16. The reflective mask according to claim 15, wherein the absorber film has a film thickness of 50 nm or less, and
the buffer layer has a film thickness of 10 nm or less.

17. The reflective mask according to claim 13, wherein the absorber film further comprises oxygen (O), and a content of the oxygen (O) is 5 atom % or more.

18. The reflective mask according to claim 7, wherein the additive element comprises tantalum (Ta), and a content ratio between Ir and Ta (Ir:Ta) is 4:1 to 22:1.

19. The reflective mask according to claim 18, wherein the absorber film further comprises oxygen (O), and a content of the oxygen (O) is 5 atom % or more.

20. The reflective mask blank according to claim 1, further comprising an etching mask film above the absorber film and wherein the etching mask film comprises chromium (Cr) and one or more elements selected from a group consisting of oxygen (O), nitrogen (N), carbon (C), boron (B), and hydrogen (H).

21. The reflective mask blank according to claim 5, further comprising an etching mask film above the absorber film and wherein the etching mask film comprises chromium (Cr) and an atom % of Cr in the etching mask blank film is different than an atom % of Cr in the buffer layer.

22. The reflective mask according to claim 7, further comprising an etching mask film above the absorber film and wherein the etching mask film comprises chromium (Cr) and one or more elements selected from a group consisting of oxygen (O), nitrogen (N), carbon (C), boron (B), and hydrogen (H).

23. The reflective mask according to claim 15, further comprising an etching mask film above the absorber film and wherein the etching mask film comprises chromium (Cr) and an atom % of Cr in the etching mask blank film is different than an atom % of Cr in the buffer layer.
